(19) United States
(12) Patent Application Publication
(10) Pub. No.: US 2026/0255862 A1
(43) Pub. Date: Aug. 27, 2026

(54) DISPLAY DEVICE

(71) Applicant: LG Display Co., Ltd., Seoul (KR)

(72) Inventors: JunHyuk SONG, Seoul (KR); SungJoon MIN, Goyang-si (KR); Yeonjun OH, Incheon (KR); Dojoong KIM, Seoul (KR); Taehyun KIM, Uijeongbu-si (KR)

(21) Appl. No.: 19/434,815

(22) Filed: Dec. 29, 2025

(30) Foreign Application Priority Data
Feb. 26, 2025 (KR) 10-2025-0025224

(51) Int. Cl. H10K 59/80

(52) U.S. Cl. CPC H10K 59/8794

(57) ABSTRACT

A display device includes a lower substrate including a plurality of rigid areas and a soft area surrounding the plurality of rigid areas, a plurality of light emitting elements disposed in each of the plurality of rigid areas, a heat dissipation unit, at least a portion of which covers the plurality of light emitting elements, and an upper substrate disposed on the plurality of light emitting elements and the heat dissipation unit, the heat dissipation unit includes a plurality of first heat dissipation layers disposed in the plurality of rigid areas and disposed on the plurality of light emitting elements, a plurality of second heat dissipation layers disposed in the soft area, and a plurality of heat dissipation lines connecting the plurality of first heat dissipation layers and the plurality of second heat dissipation layers.

### CROSS REFERENCE TO RELATED APPLICATION

This application claims priority from and the benefit of Korean Patent Application No. 10-2025-0025224, filed on Feb. 26, 2025, which is hereby incorporated by reference for all purposes as if fully set forth herein.

### BACKGROUND

### Field

Embodiments relate generally to a display device, and more particularly, to a stretchable display device.

### Discussion of the Background

Display devices used for a monitor of a computer, a TV, or a mobile phone may include an organic light emitting display (OLED) that emits light by itself, and a liquid crystal display (LCD) that requires a separate light source. Display devices have been applied in a variety of applications, including computer monitors and TVs as well as personal portable devices, and research is being conducted on display devices that have a large display area and have a reduced volume and weight. In addition, a display device which is manufactured by forming a display part, a line, and the like on a flexible substrate such as plastic which is a flexible material to be stretchable in a specific direction and may be changed into various shapes is attracting attention as a next-generation display device.

The above information disclosed in this Background section is only for understanding of the background of the inventive concepts, and, therefore, it may contain information that does not constitute prior art.

### SUMMARY

An embodiment of the invention provides a stretchable display device.

An embodiment of the invention also provides a stretchable display device with minimized heat generation.

An embodiment of the invention also provides a stretchable display device that efficiently dissipates heat of a light emitting element to the outside of the display device.

An embodiment of the invention also provides a stretchable display device having a heat dissipation path that dissipates heat generated from a pixel to the outside of the display device.

An embodiment of the invention also provides a stretchable display device having a heat dissipating function and a heat dissipating unit functioning as a black matrix.

Additional features of the inventive concepts will be set forth in the description which follows, and in part will be apparent from the description, or may be learned by practice of the inventive concepts.

According to an aspect of the present disclosure, a display device includes a lower substrate including a plurality of rigid areas and a soft area surrounding the plurality of rigid areas, a plurality of light emitting elements disposed in each of the plurality of rigid areas, a heat dissipation unit at least a portion of which covers the plurality of light emitting elements, and an upper substrate disposed on the plurality of light emitting elements and the heat dissipation unit, the heat dissipation unit includes a plurality of first heat dissipation layers disposed in the plurality of rigid areas and covering the plurality of light emitting elements, a plurality of second heat dissipation layers disposed in the soft area, and a plurality of heat dissipation lines connecting the plurality of first heat dissipation layers and the plurality of second heat dissipation layers.

The upper substrate may include a plurality of holes overlapping the soft area, and the plurality of second heat dissipation layers may be disposed in the plurality of holes.

The plurality of second heat dissipation layers may extend to the outside of the plurality of holes, and edges of the plurality of second heat dissipation layers may be disposed to cover edges of the plurality of holes.

The plurality of first heat dissipation layers may correspond to the plurality of rigid areas one-to-one.

Each of the plurality of first heat dissipation layers may be disposed to contact the plurality of light emitting elements.

The display device may further include a plurality of first plate patterns disposed between the plurality of light emitting elements and the lower substrate in the plurality of rigid areas, and a plurality of first line patterns which is disposed in the soft area and connects the plurality of first plate patterns to each other, in which the plurality of second heat dissipation layers may overlap an area between the plurality of first line patterns.

The display device may further include a plurality of connection lines disposed on the plurality of first line patterns, in which the plurality of connection lines and the plurality of heat dissipation lines may not overlap each other.

The plurality of connection lines and the plurality of heat dissipation lines may have a sinusoidal shape.

The upper substrate may be in contact with a portion of the lower substrate exposed from the plurality of first plate patterns and the plurality of first line patterns, and the upper substrate may be disposed to surround the plurality of light emitting elements on the plurality of first plate patterns.

The plurality of first heat dissipation layers may include a base material and a first conductive material, the plurality of second heat dissipation layers may include a base material and a second conductive material, the first conductive material may be a nanowire, and the second conductive material may be a thermally conductive filler made of a conductive material.

The plurality of first heat dissipation layers may be transparently configured, and the plurality of second heat dissipation layers may be opaque.

The upper substrate may further include a plurality of additional holes overlapping the plurality of rigid areas, and a part of the plurality of first heat dissipation layers may be exposed from the plurality of additional holes.

A size of each of the plurality of additional holes may be smaller than a size of each of the plurality of first heat dissipation layers.

According to another aspect of the present disclosure, a display device includes a lower substrate, a plurality of first plate patterns disposed on the lower substrate and spaced apart from each other, a plurality of first line patterns disposed between the plurality of first plate patterns, a plurality of light emitting elements disposed on the plurality of first plate patterns, a plurality of first heat dissipation layers disposed on the plurality of first plate patterns and the plurality of light emitting elements and being in contact with the plurality of light emitting elements, a plurality of heat dissipation lines extending from the plurality of first heat dissipation layers to an area between the plurality of first plate patterns and an area between the plurality of first line patterns, an upper substrate covering the plurality of first heat dissipation layers and the plurality of heat dissipation lines, and including a plurality of holes, and a plurality of second heat dissipation layers filled in the plurality of holes and connected to the plurality of heat dissipation lines, in which first and second connection lines disposed on the plurality of first line patterns extend in first and second directions, respectively, and the plurality of heat dissipation lines extend in a direction different from the first and second directions.

The upper substrate may include a portion bonded to a surface of the lower substrate and curved along a surface of a configuration located between the upper substrate and the lower substrate, and the plurality of heat dissipation lines may include a portion curved along a surface shape of the upper substrate.

The plurality of heat dissipation lines may be bent on the side surfaces of the plurality of first plate patterns and extend toward the plurality of first heat dissipation layers on the plurality of first plate patterns.

The upper substrate may further include a plurality of additional holes corresponding to each of the plurality of first heat dissipation layers one-to-one, and a diameter of each of the plurality of additional holes may be smaller than a minimum width of each of the plurality of first heat dissipation layers.

The first and second connection lines, and the plurality of heat dissipation lines may be formed in a sinusoidal shape.

The plurality of first heat dissipation layers may be configured to be transparent, and the plurality of second heat dissipation layers may be configured to be opaque.

According to still another aspect of the present disclosure, a display device includes a lower substrate including a plurality of rigid areas and a soft area surrounding the plurality of rigid areas, a plurality of light emitting elements respectively disposed in the plurality of rigid areas, a heat dissipation unit thermally connected to the plurality of light emitting elements, and an upper substrate disposed over the plurality of light emitting elements and the heat dissipation unit, in which the heat dissipation unit includes a plurality of first heat dissipation layers respectively disposed in the plurality of rigid areas and on the plurality of light emitting elements, a plurality of second heat dissipation layers disposed in the soft area, and a plurality of heat dissipation lines extending between the plurality of first heat dissipation layers and the plurality of second heat dissipation layers, the plurality of heat dissipation lines thermally connecting the plurality of first heat dissipation layers and the plurality of second heat dissipation layers, in which the plurality of first heat dissipation layers, the plurality of second heat dissipation layers, and the plurality of heat dissipation lines together form a continuous thermal-dissipation path configured to dissipate heat generated by the plurality of light emitting elements to an exterior of the display device.

It is to be understood that both the foregoing general description and the following detailed description are exemplary and explanatory and are intended to provide further explanation of the invention as claimed.

### BRIEF DESCRIPTION OF DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a plan view of a display device according to an embodiment of the invention.

FIG. 2 is a schematic enlarged plan view of area A shown in FIG. 1.

FIG. 3 is a cross-sectional view taken along line III-III' of FIG. 2.

FIG. 4 is a cross-sectional view taken along line IV-IV’ of FIG. 2.

FIGS. 5A, 5B, and 5C are process diagrams for explaining a manufacturing process of a heat dissipation unit of a display device according to an embodiment of the invention.

FIG. 6 is a schematic enlarged plan view of a display device according to an embodiment of the invention.

FIG. 7 is a cross-sectional view taken along line VII-VII' of FIG. 6.

FIGS. 8A and 8B are process diagrams for explaining a process of manufacturing a heat dissipation unit of a display device according to an embodiment of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

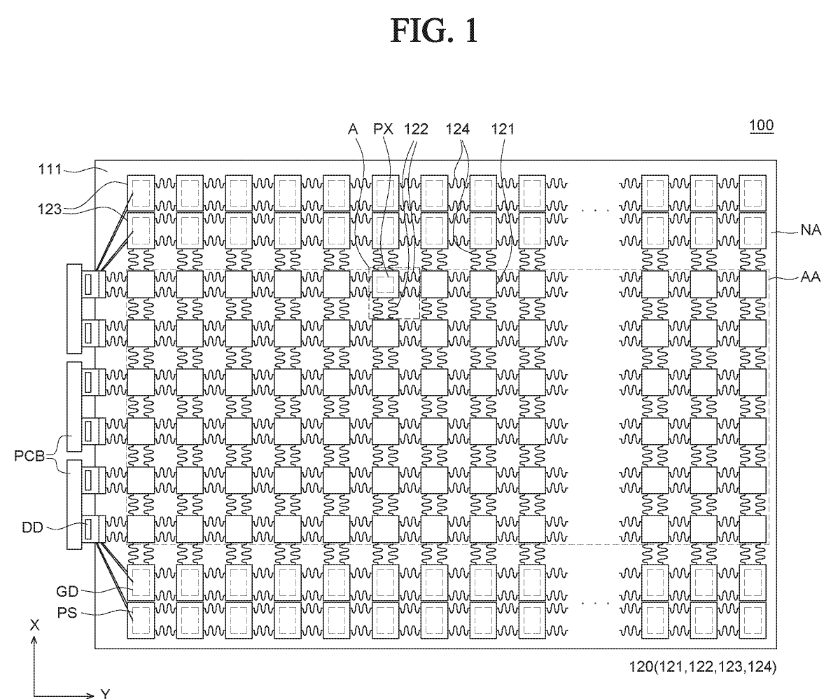

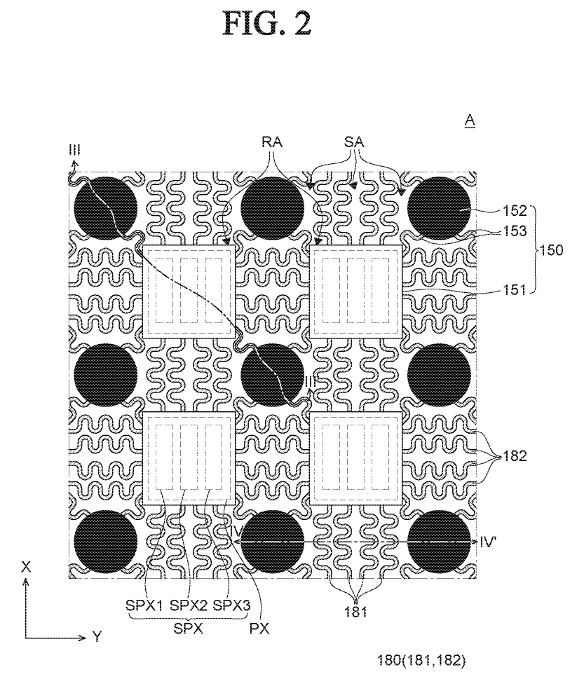

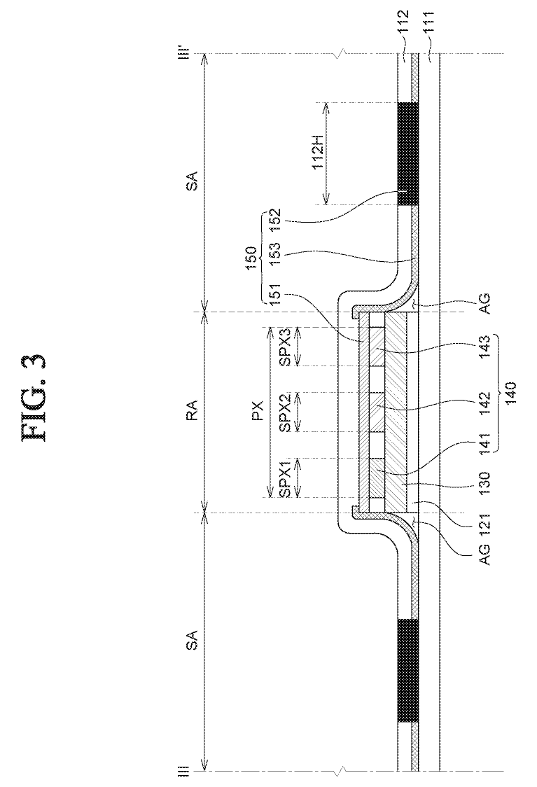

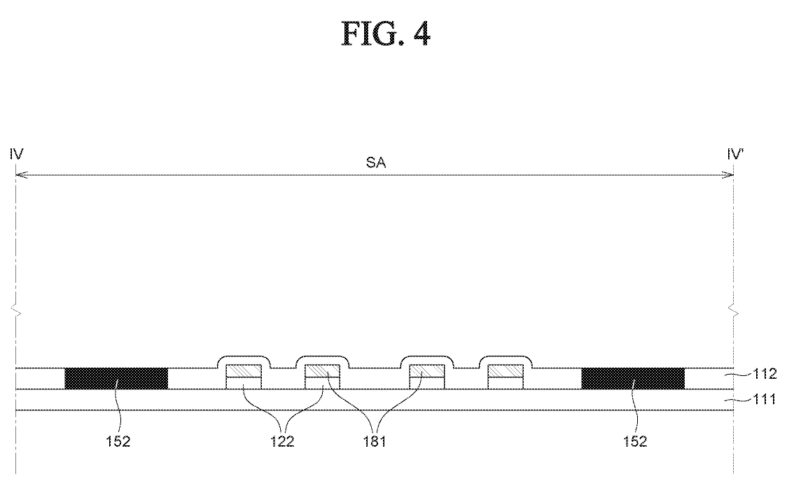

FIG. 1 is a plan view of a display device according to an embodiment of the invention. FIG. 2 is a schematic enlarged plan view of area A shown in FIG. 1. FIG. 3 is a cross-sectional view taken along line III-III' of FIG. 2. FIG. 4 is a cross-sectional view taken along line IV-IV’ of FIG. 2.

First, the display device 100 according to an embodiment of the invention is a display device capable of displaying an image even when it is bent or stretched, and may also be referred to as a stretchable display device, a flexible display device, and a retractable display device. The display device 100 may have not only high flexibility but also stretchability compared to a conventional general display device. Accordingly, not only may a user bend or stretch the display device 100, but the shape of the display device 100 may be freely changed according to manipulation by the user. For example, when the user holds and pulls an end of the display device 100, the display device 100 may be stretched in a direction in which the user pulls the display device 100. Alternatively, when the user applies a force to dispose the display device 100 on a non-flat surface, the display device 100 may correspondingly bend along the shape of the non-flat surface. In addition, when the force applied by the user is removed, the display device 100 may be restored to its original shape.

Referring to FIGS. 1, 2, 3 and 4 , a lower substrate 111 may relate to several components of the display device 100, and an upper substrate 112 may relate to several components of the display device 100.

Each of the lower substrate 111 and the upper substrate 112 is a flexible substrate and may be formed of an insulating material that may be bent, stretched, or reversibly expanded and contracted. For example, each of the lower substrate 111 and the upper substrate 112 may be made of a silicone rubber such as polydimethylsiloxane (PDMS) or an elastomer such as polyurethane (PU) and polytetrafluoroethylene (PTFE) and thus have flexibility. The materials of the lower substrate 111 and the upper substrate 112 may be the same, but are not limited thereto and may be variously modified.

The lower substrate 111 may have a display area AA in which images are displayed and a non-display area NA excluding the display area AA. The display area AA is an area in which images are displayed in the display device 100. The non-display area NA is an area in which a configuration for driving a plurality of pixels PX disposed in the display area AA is disposed. For example, a plurality of pixels PX may be disposed in the display area AA, and a gate driver GD and a power supply PS may be disposed in the non-display area NA.

The lower substrate 111 may also include a plurality of rigid areas RA and soft area SA. The plurality of rigid areas RA may be disposed to be spaced apart from each other. The plurality of rigid areas RA may be areas of the lower substrate 111 overlapping a plurality of first plate patterns 121 and a plurality of second plate patterns 123. The plurality of rigid areas RA may be areas in which the plurality of first plate patterns 121 and the plurality of second plate patterns 123 are disposed, and may impart rigidity to the plurality of rigid areas RA.

The soft area SA may be an area surrounding each of the plurality of rigid areas RA. The soft area SA may be an area that does not overlap the plurality of first plate patterns 121 and the plurality of second plate patterns 123. The soft area SA is an area between the plurality of first plate patterns 121 and the plurality of second plate patterns 123, and may include an area in which the plurality of first line patterns 122 and the plurality of second line patterns 124 are disposed. In addition, the soft area SA may include an area in which a pattern layer 120 is not disposed. Since the soft area SA may be an area in which the plurality of first plate patterns 121 and the plurality of second plate patterns 123 are not disposed, the soft area SA may accordingly be flexibly deformable.

Accordingly, the plurality of first plate patterns 121 and the plurality of second plate patterns 123 are disposed in the plurality of rigid areas RA, and the plurality of first plate patterns 121 and the plurality of second plate patterns 123 are not disposed in the soft area SA. Therefore, the plurality of rigid areas RA may have more rigid characteristics than the soft area SA.

According to an embodiment, the display area AA, the non-display area NA, the soft area SA, and the plurality of rigid areas RA are not limited to the lower substrate 111, but may correspond throughout the display device 100.

The pattern layer 120 is disposed on the lower substrate 111. The pattern layer 120 includes a plurality of first plate patterns 121 and a plurality of first line patterns 122 disposed in the display area AA, a plurality of second plate patterns 123 and a plurality of second line patterns 124 disposed in the non-display area NA.

The plurality of first plate patterns 121 and the plurality of second plate patterns 123 may be substrates on which a pixel PX, a gate driver GD, and a power supply PS are formed. The plurality of first plate patterns 121 and the plurality of second plate patterns 123 may be disposed on the lower substrate 111 and spaced apart from each other, such as in island shapes, but are not limited thereto. For example, the plurality of first plate patterns 121 and the plurality of second plate patterns 123 may be arranged in a matrix form. Meanwhile, as shown in FIG. 2, the plurality of first plate patterns 121 and the plurality of second plate patterns 123 have a rectangular shape. However, the shapes thereof are not limited thereto.

The plurality of first line patterns 122 may connect the first plate patterns 121 adjacent to each other, and the plurality of second line patterns 124 may connect the first plate patterns 121 and the second plate patterns 123 adjacent to each other, or connect the plurality of

second plate patterns 123 adjacent to each other. The plurality of first line patterns 122 and the plurality of second line patterns 124 may have a curved shape, such as, for example, a sinusoidal shape, but are not limited thereto.

The plurality of first plate patterns 121, the plurality of first line patterns 122, the plurality of second plate patterns 123, and the plurality of second line patterns 124 may be rigid patterns. For example, the plurality of first plate patterns 121, the plurality of first line patterns 122, the plurality of second plate patterns 123, and the plurality of second line patterns 124 may be rigid compared to the lower substrate 111 and the upper substrate 112. Accordingly, an elastic modulus and a hardness of the plurality of first plate patterns 121, the plurality of first line patterns 122, the plurality of second plate patterns 123, and the plurality of second line patterns 124 may be higher than the elastic modulus and the hardness of the lower substrate 111 and the upper substrate 112. For example, the elastic modulus of the plurality of first plate patterns 121, the plurality of first line patterns 122, the plurality of second plate patterns 123, and the plurality of second line patterns 124 may be 1000 times higher than the elastic modulus of the lower substrate 111 and the upper substrate 112, but is not limited thereto.

The plurality of first plate patterns 121, the plurality of first line patterns 122, the plurality of second plate patterns 123, and the plurality of second line patterns 124 may be formed of a plastic material having lower flexibility than the lower substrate 111 and the upper substrate 112.

Referring to FIG. 1, a gate driver GD may be mounted on a plurality of second plate patterns 123. The gate driver GD is a component that supplies a gate voltage to the plurality of pixels PX disposed in the display area AA. For example, the gate driver GD may include a plurality of stages formed on the plurality of second plate patterns 123, and each stage of the gate driver GD may be electrically connected to each other through a plurality of connection lines 180. Accordingly, the gate voltage output from one stage may be transmitted to another stage. Further, each stage may sequentially supply a gate voltage to a plurality of pixels PX connected to each stage.

A power supply PS may be mounted on the plurality of second plate patterns 123. The power supply PS may be electrically connected to the gate driver GD and the plurality of pixels PX. For example, the power supply PS may supply a gate driving voltage and a gate clock voltage to the gate driver GD. Further, the power supply PS is connected to the plurality of pixels PX to supply a pixel driving voltage to each of the plurality of pixels PX.

The printed circuit board PCB is a component that may include a control unit such as an integrated circuit (IC) chip, a circuit, and/or a memory, a processor, etc., to transmit signals and voltages for driving the pixel PX from the control unit to the pixel PX. The printed circuit board PCB may include a stretchable area and a non-stretchable area. For example, the IC chip, circuit, memory, processor, etc. may be mounted in the non-stretchable area, and lines electrically connected to the IC chip, the circuit, the memory, and the processor may be disposed in the stretchable area.

The data driver DD is a component that supplies a data voltage to the plurality of pixels PX disposed in the display area AA. The data driver DD may be configured in the form of an IC chip, and therefore the data driver DD may also be referred to as a data integrated circuit D-IC.

Referring to FIG. 2 and FIG. 3, a pixel PX including a plurality of sub-pixels SPX is disposed on the first plate pattern 121. Each of the plurality of sub-pixels SPX may include a light emitting element 140 and a circuit part 130 for driving the light emitting element 140. The plurality of sub-pixels SPX constituting one pixel PX may include a first sub-pixel SPX1, a second sub-pixel SPX2, and a third sub-pixel SPX3. The first sub-pixel SPX1, the second sub-pixel SPX2, and the third sub-pixel SPX3 may respectively be a red sub-pixel, a green sub-pixel, and a blue sub-pixel, but are not limited thereto.

The circuit part 130 for driving the plurality of light emitting elements 140 is disposed on the first plate pattern 121. The circuit part 130 may include various elements and a plurality of lines. The elements included in the circuit part 130 may be configured in various ways. For example, the circuit part 130 may include elements such as a driving transistor, one or more switching transistors, and a storage capacitor, but are not limited thereto.

The plurality of lines included in the circuit part 130 may also be configured in various ways. For example, the plurality of lines may include a gate line, a data line, a high potential voltage line, a low potential voltage line, and a reference voltage line, but are not limited thereto.

The circuit part 130 may include various insulating layers to allow various elements and lines to be stacked together therein. For example, a buffer layer, a gate insulating layer, an interlayer insulating layer, a passivation layer, a planarization layer, and a bank may be disposed together in the circuit part 130.

The light emitting element 140 is disposed in each of the plurality of sub-pixels SPX on the circuit part 130. The light emitting element 140 may include a first light emitting element 141 of the first sub-pixel SPX1, a second light emitting element 142 of the second sub-pixel SPX2, and a third light emitting element 143 of the third sub-pixel SPX3. The first light emitting element 141, the second light emitting element 142, and the third light emitting element 143 may respectively be a red light emitting element, a green light emitting element, and a blue light emitting element, but are not limited thereto. The light emitting element 140 may be a light emitting element (LED), a micro light emitting element (micro-LED), or an organic light emitting element (OLED), but is not limited thereto.

Further, when the light emitting element 140 is a micro-LED, the light emitting element 140 may be connected to the circuit part 130 through a pad electrode and a conductive adhesive layer. For example, a pad electrode connected to the driving transistor is formed in the circuit part 130 and the light emitting element 140 may be bonded to the pad electrode using a conductive adhesive layer.

Next, a connection line 180 is disposed on the plurality of first line patterns 122. The connection line 180 may transmit a signal to lines on the plurality of first plate patterns 121. The connection line 180 may extend onto the plurality of first plate patterns 121 from the plurality of first line patterns 122, and be electrically connected to the lines on the plurality of first plate patterns 121. The plurality of first line patterns 122 may not be disposed in an area of the display area AA in which the connection line 180 is not disposed between the plurality of first plate patterns 121.

The connection line 180 includes a first connection line 181 and a second connection line 182. The first connection line 181 refers to a line extending in the first direction X between the plurality of first plate patterns 121 of the connection line 180, and the second connection line 182 refers to a line extending in the second direction Y between the plurality of first plate patterns 121 of the connection line 180. Accordingly, as shown in FIG. 2 and FIG. 4, the first connection line 181 and second connection line 182 overlap the plurality of first line patterns 122. The connection line 180 may be formed of various metal materials.

In the case of a general display device, various lines, such as a plurality of scan lines and a plurality of data lines, may be disposed to extend in a straight line between a plurality of sub-pixels, and the plurality of sub-pixels may be connected to one signal line. Accordingly, in the case of a general display device, various lines such as a gate line, a data line, a high potential voltage line, and a reference voltage line extend on the substrate from one side to the other side of the display device without being disconnected.

In contrast, in the case of the display device 100 according to an embodiment of the invention, various lines having a straight line shape, such as a scan line, a data line, a high potential voltage line, a reference voltage line, and an initialization voltage line, may be disposed only on the plurality of first plate patterns 121 and the plurality of second plate patterns 123.

Further, in the display device 100 according to an embodiment of the invention, lines on two adjacent first plate patterns 121 may be connected by the connection line 180. For example, a gate line may be disposed on the plurality of first plate patterns 121 disposed adjacent to each other in the first direction X, and gate pads may be disposed at both ends of the gate line. In this case, each of the plurality of gate pads on the plurality of first plate patterns 121 disposed adjacent to each other in the first direction X may be connected to each other by the first connection line 181. Therefore, the gate line disposed on the plurality of first plate patterns 121 and the first connection line 181 disposed on the first line pattern 122 may function as one gate line.

Accordingly, among various lines included in the display device 100, lines which extend in the first direction X, for example, an emission signal line, a low potential voltage line, and a high potential voltage line, may be electrically connected by the first connection line 181 as described above. Further, the second connection line 182 may connect pads on the plurality of first plate patterns 121 disposed adjacent to each other in the second direction Y. For example, the second connection line 182 may connect a pad of a data line, a high potential voltage line, a low potential voltage line, or a reference voltage line, but is not limited thereto.

Next, a heat dissipation unit 150 is formed on the plurality of light emitting elements 140. The heat dissipation unit 150 may dissipate heat generated in the pixel PX including the plurality of light emitting elements 140 to the outside of the display device 100. The heat dissipation unit 150 may be a heat sink. The heat dissipation unit 150 includes a plurality of first heat dissipation layers 151, a plurality of second heat dissipation layers 152, and a plurality of heat dissipation lines 153.

The plurality of first heat dissipation layers 151 is disposed on the plurality of light emitting elements 140. The plurality of first heat dissipation layers 151 is disposed between the plurality of light emitting elements 140 and the upper substrate 112. The plurality of first heat dissipation layers 151 may be in direct contact with the upper portions of the plurality of light emitting elements 140, and may transfer heat generated from the plurality of light emitting elements 140 to the plurality of heat dissipation lines 153 and the plurality of second heat dissipation layers 152.

Each of the plurality of first heat dissipation layers 151 may correspond respectively to each of the plurality of rigid areas RA. Accordingly, the plurality of first heat dissipation layers 151 may have a planar shape corresponding to a planar shape of the rigid area RA or a planar shape of the plurality of first plate patterns 121. For example, one first heat dissipation layer of the plurality of first heat dissipation layers 151 may be disposed on one first plate pattern of the plurality of first plate patterns 121, and the first heat dissipation layer 151 may have a rectangular planar shape. The first heat dissipation layer 151 may be in contact with all of the first light emitting element 141, the second light emitting element 142, and the third light emitting element 143 disposed on one first plate pattern 121. The first heat dissipation layer 151 may be formed in a shape other than a rectangle, but is not limited thereto.

The upper substrate 112 includes a plurality of holes 112H disposed in the soft area SA, and the plurality of second heat dissipation layers 152 is respectively disposed in each of the plurality of holes 112H. The plurality of second heat dissipation layers 152 may be disposed to fill the plurality of holes 112H. The plurality of second heat dissipation layers 152 may be disposed so as to correspond to an exposed part of the lower substrate 111 from the pattern layer 120. The plurality of second heat dissipation layers 152 may be disposed in the soft area SA, in an area between the plurality of first plate patterns 121 and the plurality of connection lines 180.

Since the plurality of second heat dissipation layers 152 are disposed in an empty space between the pattern layers 120, the plurality of second heat dissipation layers 152 may be formed in various shapes without being limited the configuration of the pattern layer 120. For example, the plurality of second heat dissipation layers 152 may be formed in a circular shape, and may also be formed in a rectangular or various polygonal shape similar to the plurality of first heat dissipation layers 151, but is not limited thereto.

The plurality of first heat dissipation layers 151 and the plurality of second heat dissipation layers 152 may be formed of a base material and a conductive material. The plurality of first heat dissipation layers 151 and the plurality of second heat dissipation layers 152 may be formed by mixing a conductive material having high thermal conductivity with a base material.

The display device 100 according to an embodiment of the invention may be a stretchable display device 100 which is flexibly deformable. The plurality of first heat dissipation layers 151 and the plurality of second heat dissipation layers 152 disposed on the upper substrate 112 side may also be configured to be flexible. Accordingly, the base material may be made of a material having elasticity such as rubber or a block copolymer material. The block copolymer material may include styrene-ethylene-Butylene-Styrene (SEBS), styrene-Butadiene-Styrene (SBS), and styrene-Isoprene-Styrene (SIS), but is not limited thereto.

The conductive material may include a first conductive material and a second conductive material. The plurality of first heat dissipation layers 151 may include a base material and a first conductive material, and the plurality of second heat dissipation layers 152 may include a base material and a second conductive material. The conductive material may be a metal material having high thermal conductivity for heat dissipation.

For example, the first conductive material may be a nanowire including a conductive material such as silver (Ag), copper (Cu), or gold (Au). The plurality of first heat dissipation layers 151 overlapping the light emitting element 140 may be transparent so that light emitted from the light emitting element 140 may be transmitted to outside the display device 100, while efficiently dissipating heat by including nanowires.

The second conductive material may be a thermally conductive filler including a conductive material such as carbon nanotubes (CNT) or carbon black. The thermally conductive filler may be added to the base material in an amount of about 30 wt % or less to prevent agglomeration of the conductive filler and minimize deterioration of the mechanical properties of the base material. The plurality of second heat dissipation layers 152 that does not overlap the plurality of light emitting elements 140 may be opaque, including a conductive filler of carbon nanotubes or carbon black. Accordingly, the second heat dissipation layer 152 located in an area between the plurality of pixels PX may function like a black matrix that prevents color mixture between the pixels PX.

The plurality of heat dissipation lines 153 is disposed between the plurality of first heat dissipation layers 151 and the plurality of second heat dissipation layers 152. The plurality of heat dissipation lines 153 may be disposed on the lower surface of the upper substrate 112. The plurality of heat dissipation lines 153 may transfer heat from the plurality of first heat dissipation layers 151 to the plurality of second heat dissipation layers 152. For example, heat dissipation lines 153 may respectively extend from four corners of a first heat dissipation layer 151 toward an adjacent second heat dissipation layer 152. The plurality of heat dissipation lines 153 may extend in a direction different from the first direction X and the second direction Y so as not to interfere with the first connection line 181 and the second connection line 182. The plurality of heat dissipation lines 153 may be made of a metal material having high thermal conductivity. For example, the plurality of heat dissipation lines 153 may be formed of a metal material such as copper (Cu), silver (Ag), molybdenum (Mo), or aluminum (Al). Further, the plurality of heat dissipation lines 153 extending from the rigid area RA toward the soft area SA may be formed in a curved shape, for example, a sinusoidal shape, so as not to affect the stretchability of the display device 100.

Meanwhile, the upper substrate 112 may be disposed in close contact with the lower substrate 111 and the configuration on the lower substrate 111. O2 plasma treatment may be performed on the surfaces of the upper substrate 112 and the lower substrate 111 to increase the interfacial energy of the surfaces of the upper substrate 112 and the lower substrate 111 and impart adhesion to the surfaces of the upper substrate 112 and the lower substrate 111. Accordingly, instead of bonding the upper substrate 112 and the lower substrate 111 by depositing a separate adhesive layer between the upper substrate 112 and the lower substrate 111, adhesion may be applied to the surfaces of the upper substrate 112 and the lower substrate 111 to bond the upper substrate 112 to the lower substrate 111 and the components on the lower substrate 111.

The upper substrate 112 may have a curved shape, as the upper substrate 112 is disposed in close contact with the lower substrate 111 and the configuration of elements on the lower substrate 111. For example, the upper substrate 112 may be disposed to be curved along surfaces of the components on the plurality of first plate patterns 121 and the components on the plurality of first line patterns 122. The upper substrate 112 is attached to the lower substrate 111 and is disposed to surround the plurality of light emitting elements 140 on the first plate pattern 121. The upper substrate 112 may be in contact with a portion of the upper surface of the lower substrate 111 exposed from the pattern layer 120. The upper substrate 112 may be in contact with the connection line 180 on the pattern layer 120 and the components of the pixel PX.

The plurality of heat dissipation lines 153 disposed on a lower surface of the upper substrate 112 may be disposed to be curved along the lower surface of the upper substrate 112. For example, when a heat dissipation line of the plurality of heat dissipation lines 153 extends toward a first plate pattern of the plurality of first plate patterns 121 from the horizontal surface between the lower substrate 111 and the upper substrate 112, the heat dissipation line 153 may be disposed or bent in a vertical direction along a side surface of the first plate pattern 121 and connected to a first heat dissipation layer of the plurality of first heat dissipation layers 151 located on the first plate pattern 121.

The upper substrate 112 and the heat dissipation line 153 disposed on the side surface of the first plate pattern 121 may not be in close contact with both the side surfaces of the first plate pattern 121 and the configuration of elements on the first plate pattern 121 due to a step from the first plate pattern 121 to the first heat dissipation layer 151, and an air gap AG may occur between the upper substrate 112 and the side surface of the first plate pattern 121. However, since the upper substrate 112 is bonded to the surface of the lower substrate 111 around the first plate pattern 121 and the configuration of elements on the first plate pattern 121, even if an air gap AG occurs, the first plate pattern 121 and the configuration of elements on the first plate pattern 121 may be protected.

Meanwhile, since the upper substrate 112 is bonded to the lower substrate 111, at least a portion of the heat dissipation line 153 disposed on the lower surface of the upper substrate 112 may be disposed in close contact with the lower substrate 111. The heat dissipation line 153 may be disposed in an area in which the first connection line 181 and the second connection line 182 are not disposed, so that the heat dissipation line 153, the first connection line 181, and the second connection line 182 do not interfere with each other. In particular, the connection line 180 and the heat dissipation line 153 do not overlap each other. The first connection line 181 extends in the first direction X, the second connection line 182 extends in the second direction Y, but the heat dissipation line 153 may extend in a direction different from the first direction X and the second direction Y, and the connection line 180 may be avoided.

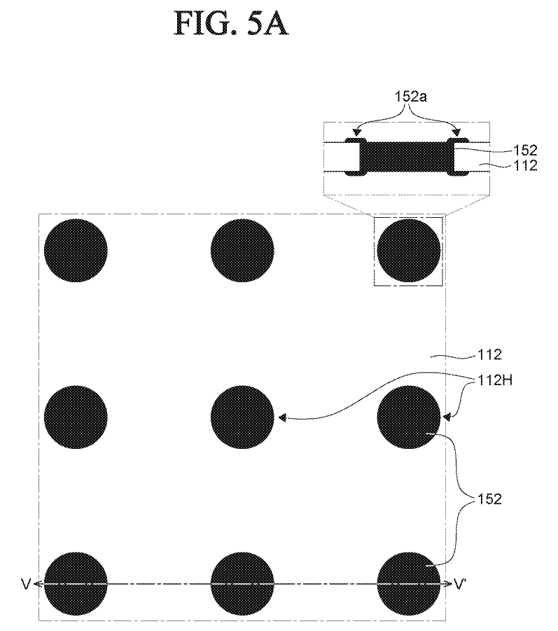

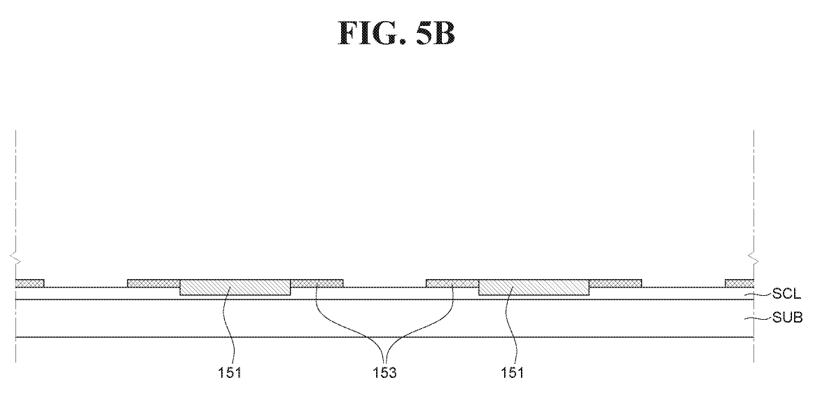

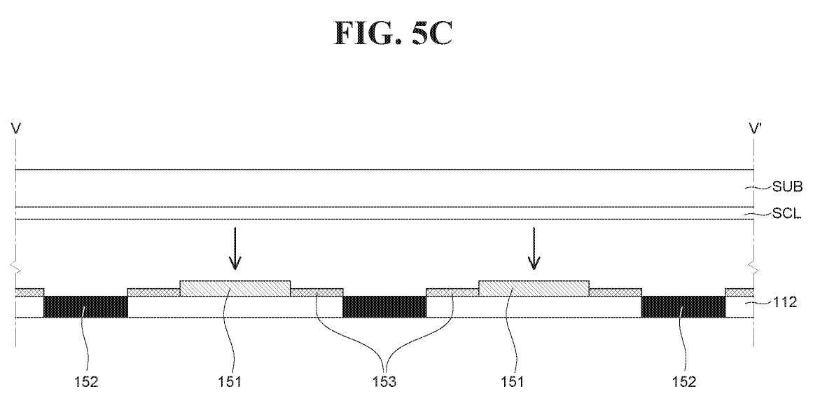

Hereinafter, a process of manufacturing the heat dissipation unit 150 of the display device 100 according to an embodiment of the invention will be described with reference to FIG. 5A, FIG. 5B, and FIG. 5C.

FIG. 5A, FIG. 5B, and FIG. 5C are process diagrams for explaining a manufacturing process of a heat dissipation unit of a display device according to an exemplary embodiment of the present disclosure. Specifically, FIG. 5A is a schematic plan view of the upper substrate 112, FIG. 5B is a cross-sectional view of a temporary substrate SUB having the plurality of heat dissipation lines 153 and the plurality of first heat dissipation layers 151 formed thereon, and FIG. 5C is a cross-sectional view taken along the line V-V’ of FIG. 5A.

Referring to FIG. 5A, a plurality of holes 112H is formed in the upper substrate 112, and a plurality of second heat dissipation layers 152 is respectively formed in each of the plurality of holes 112H. The plurality of holes 112H may be formed to correspond to an empty space between a plurality of connection lines 180 in the soft area SA. The plurality of second heat dissipation layers 152 may be formed by filling each of the plurality of holes 112H with a material forming the second heat dissipation layer 152 and a base material in which the second conductive material is mixed.

In order to suppress the separation of the second heat dissipation layer 152 from the upper substrate 112, at least a part of the second heat dissipation layer 152 may be disposed to extend to the outside of the plurality of holes 112H. For example, a part of the second heat dissipation layer 152 may protrude to the outside of the hole 112H and may be in contact with the upper and lower surfaces of the upper substrate 112. For example, an edge 152a of the second heat dissipation layer 152 may be disposed to cover each of an upper edge and a lower edge of the hole 112H. The edge 152a of the second heat dissipation layer 152 may protrude to the outside of the hole 112H, thereby increasing a contact area between the second heat dissipation layer 152 and the upper substrate 112 and improving adhesion between the second heat dissipation layer 152 and the upper substrate 112.

Referring to FIG. 5B, a plurality of heat dissipation lines 153 and a plurality of first heat dissipation layers 151 are formed on the temporary substrate SUB and the sacrificial layer SCL. The temporary substrate SUB is a member in which a plurality of first heat dissipation layers 151 and a plurality of heat dissipation lines 153 are temporarily formed. The sacrificial layer SCL may separate the plurality of first heat dissipation layers 151 and the plurality of heat dissipation lines 153 from the temporary substrate SUB. The sacrificial layer SCL may be formed from hydrogenated amorphous silicon or hydrogenated and impurity-doped amorphous silicon.

Referring to FIG. 5C, when a laser is irradiated from the rear surface of the temporary substrate SUB to the temporary substrate SUB, hydrogen in the sacrificial layer SCL may be dehydrogenated and the first heat dissipation layer 151 and the heat dissipation line 153 may be separated from the sacrificial layer SCL and the temporary substrate SUB. Accordingly, the first heat dissipation layer 151 and the heat dissipation line 153 may be separated from the temporary substrate SUB and transferred to the upper substrate 112 on which the second heat dissipation layer 152 is formed, to form the heat dissipation unit 150 on the upper substrate 112 side. Further, the upper substrate 112 on which the heat dissipation unit 150 is formed is bonded to the lower substrate 111 to complete the manufacturing process of the display device 100.

Accordingly, the display device 100 according to an embodiment of the invention includes the heat dissipation unit 150 to effectively dissipate heat generated from the plurality of light emitting elements 140. By connecting the heat dissipation unit 150 to the plurality of pixels PX to form a path for dissipating heat, heat generated in the pixels PX may be discharged to the outside of the display device 100.

For example, in each of the plurality of pixels PX, the plurality of first heat dissipation layers 151 covering the plurality of light emitting elements 140, the plurality of second heat dissipation layers 152 penetrating the upper substrate 112, and the plurality of heat dissipation line 153 connecting the plurality of first heat dissipation layers 151 and the plurality of second heat dissipation layers 152 are formed such that heat generated from the plurality of light emitting elements 140 may be discharged to the outside of the display device 100.

The plurality of first heat dissipation layers 151, the plurality of second heat dissipation layers 152, and the plurality of heat dissipation lines 153 may include a material having high thermal conductivity. For example, the plurality of second heat dissipation layers 152 may comprise carbon nanotubes. The thermal conductivity of the carbon nanotubes may be in a range of about 1000 W/m·K to 6000 W/m·K, which is thousands to tens of thousands of times higher than the thermal conductivity of air, which may be in a range of about 0.024 W/m·K to 0.026 W/m·K. Accordingly, the plurality of second heat dissipation layers 152 having a higher thermal conductivity than air may be filled in the hole 112H of the upper substrate 112 to more effectively dissipate heat.

Meanwhile, in the related art, a resin layer having an adhesive force is filled between the upper substrate and the lower substrate to bond the upper substrate and the lower substrate to each other, and the components between the upper substrate and the lower substrate are protected. However, in such a structure, the resin layer may surround all of the plurality of light emitting elements, causing heat generated from the plurality of light emitting elements to be trapped between the upper substrate and the lower substrate, thereby making it difficult for the heat to dissipate to the outside. Accordingly, there may be a problem in the related art in that some components are delaminated or performance is deteriorated due to heat generation.

Accordingly, in the display device 100 according to an embodiment of the invention, the resin layer may not be filled between the lower substrate 111 and the upper substrate 112, and the heat dissipation unit 150 and the upper substrate 112 may be disposed on the configuration of elements on the lower substrate 111 to protect the configuration of elements between the upper substrate 112 and the lower substrate 111. By subjecting the surfaces of the upper substrate 112 and the lower substrate 111 to plasma treatment to impart an adhesive force to the surfaces of the upper substrate 112 and the lower substrate 111, the upper substrate 112 and the lower substrate 111 may be bonded together without requiring an adhesive layer.

Accordingly, the heat dissipation unit 150 formed on the upper substrate 112 side may be disposed in close contact with the configuration of elements on the lower substrate 111 and easily dissipate heat generated from the configuration on the lower substrate 111, for example, the pixel PX to the outside of the display device 100. Therefore, a resin layer which traps heat between the upper substrate 112 and the lower substrate 111 may be removed, and instead, the heat dissipation unit 150 is formed to form a heat dissipation path which may dissipate heat generated from the light emitting element 140 to the outside of the display device 100.

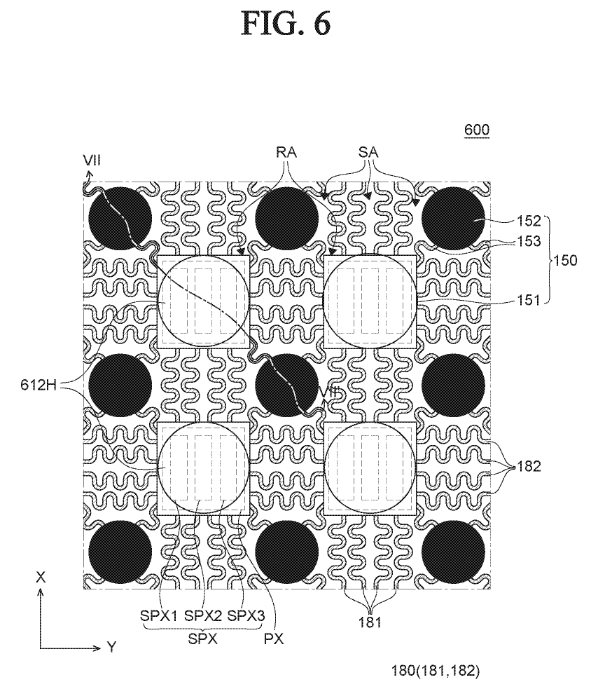

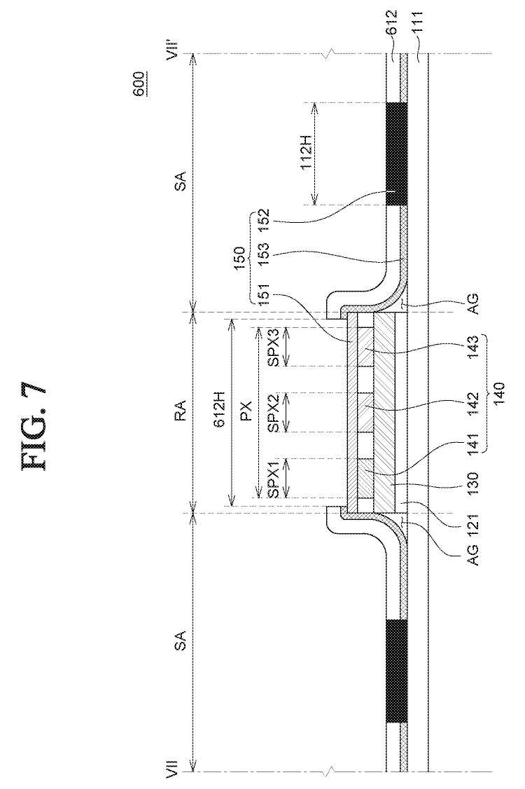

FIG. 6 is a schematic enlarged plan view of a display device 600 according to another embodiment of the invention. FIG. 7 is a cross-sectional view taken along line VII-VII' of FIG. 6. The display device 600 in FIG. 6 and FIG. 7 has the substantially same configuration as the display device 100 in FIGS. 1 to 4, and the disclosure thereof is incorporated herein by reference, except that the upper substrate 612 further includes an additional hole 612H, so that a redundant description will be omitted.

Referring to FIG. 6 and FIG. 7, the upper substrate 612 further includes a plurality of additional holes 612H. The plurality of additional holes 612H may overlap a plurality of first heat dissipation layers 151 and a plurality of rigid areas RA. Each of the plurality of additional holes 612H may respectively correspond to the each of the plurality of first heat dissipation layers 151 and the plurality of rigid areas RA.

The size of an additional hole of the plurality of additional holes 612H may be equal to or smaller than the size of a rigid area RA of the plurality of rigid areas RA. A diameter of the additional hole 612H may be smaller than a minimum width of a first heat dissipation layer of the plurality of first heat dissipation layers 151. The size of the additional hole 612H is formed to be smaller than that of the first heat dissipation layer 151, so that separation of the first heat dissipation layer 151 from the additional hole 612H may be prevented.

Further, the additional holes 612H may overlap the plurality of light emitting elements 140 of the configuration on the first plate pattern 121. One additional hole 612H may overlap the plurality of light emitting elements 140 included in one pixel PX.

The plurality of first heat dissipation layers 151 may be exposed to the outside of the display device 600 by the plurality of additional holes 612H. Accordingly, heat generated in the display device 600 may be discharged to the outside thereof through the first heat dissipation layer 151 exposed to the outside in the additional hole 612H and the second heat dissipation layer 152 exposed in the hole 112H.

Meanwhile, the additional hole 612H may have a larger size than the hole 112H, but the additional hole 612H may be configured in various sizes in consideration of the size of the rigid area RA, the light emitting element 140, the first heat dissipation layer 151, and the like, but is not limited thereto.

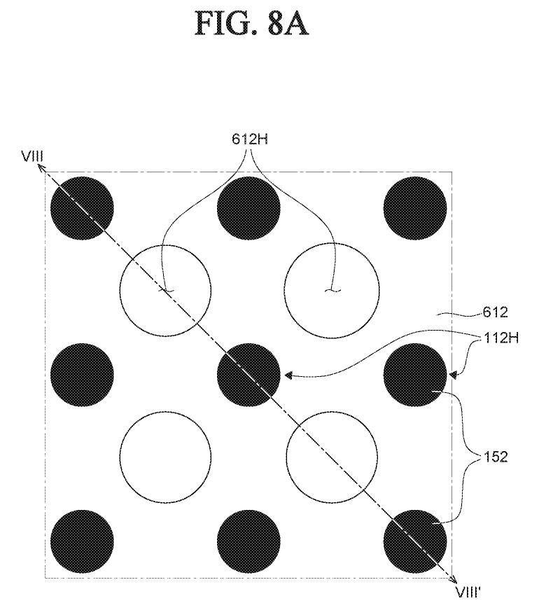

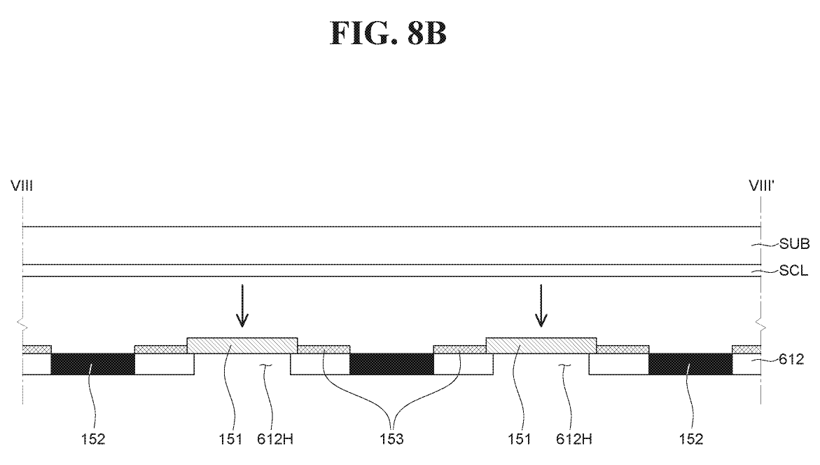

FIG. 8A and FIG. 8B are process diagrams for explaining a process of manufacturing a heat dissipation unit of a display device 600 according to an embodiment of the invention. Specifically, FIG. 8A is a schematic plan view of an upper substrate 612, and FIG. 8B is a cross-sectional view taken along line VIII-VIII' of FIG. 8A.

Referring to FIG. 8A, a plurality of holes 112H and a plurality of additional holes 612H may be formed in the upper substrate 612. Further, a material constituting the second heat dissipation layer 152 may be filled in the plurality of holes 112H to form the second heat dissipation layer 152.

Next, referring to FIG. 8B, a plurality of first heat dissipation layers 151 and a plurality of heat dissipation lines 153 are formed on the temporary substrate SUB and the sacrificial layer SCL.

Further, the plurality of first heat dissipation layers 151 and the plurality of heat dissipation lines 153 are separated from the temporary substrate SUB and transferred to the upper substrate 612 to form the heat dissipation unit 150. The first heat dissipation layer 151 may be transferred onto the additional hole 612H.

As described above, the size of the additional hole 612H may be smaller than the size of the first heat dissipation layer 151 so that the first heat dissipation layer 151 does not deviate from the upper substrate 612 through the additional hole 612H, and the first heat dissipation layer 151 may be seated on the upper substrate 612. At least an edge of a part of the first heat dissipation layer 151 may be in contact with the upper substrate 612 so that the first heat dissipation layer 151 may be seated on one surface of the upper substrate 612.

Accordingly, in the display device 600 according to an embodiment of the invention, the additional hole 612H overlapping the first heat dissipation layer 151 is formed in the upper substrate 612 to directly discharge the heat from the first heat dissipation layer 151 to the outside of the display device 600 through the additional hole 612H. The first heat dissipation layer 151 may be exposed to the outside of the display device 600 by the additional hole 612H. Heat from the first heat dissipation layer 151 may be transferred to the heat dissipation line 153 and the second heat dissipation layer 152 to be discharged to the outside of the display device 600, or may be immediately discharged to the outside of the display device 600 through the additional hole 612H. Accordingly, heat generated in the pixel PX may be discharged to the outside of the display device 600 through both the first heat dissipation layer 151 and the second heat dissipation layer 152 so that heat generated by the display device 600 may be more efficiently minimized, thereby improving the reliability of the display device 600.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device, comprising:
a lower substrate including a plurality of rigid areas and a soft area surrounding the plurality of rigid areas;
a plurality of light emitting elements disposed in each of the plurality of rigid areas;
a heat dissipation unit, at least a portion of which is disposed on the plurality of light
emitting elements; and
an upper substrate disposed on the plurality of light emitting elements and the heat dissipation unit,
wherein the heat dissipation unit includes:
a plurality of first heat dissipation layers disposed in the plurality of rigid areas and
disposed on the plurality of light emitting elements;
a plurality of second heat dissipation layers disposed in the soft area; and
a plurality of heat dissipation lines connecting the plurality of first heat dissipation layers
and the plurality of second heat dissipation layers.

2. The display device according to claim 1, wherein the upper substrate includes a
plurality of holes overlapping the soft area, and
the plurality of second heat dissipation layers is disposed in the plurality of holes.

3. The display device according to claim 2, wherein the plurality of second heat
dissipation layers extends to an outside of the plurality of holes, and edges of the plurality of
second heat dissipation layers are disposed to cover edges of the plurality of holes.

4. The display device according to claim 1, wherein each of the plurality of first heat
dissipation layers corresponds to each of the plurality of rigid areas.

5. The display device according to claim 1, wherein each of the plurality of first heat
dissipation layers contacts the plurality of light emitting elements.

6. The display device according to claim 1, further comprising:
a plurality of first plate patterns disposed between the plurality of light emitting elements
and the lower substrate in the plurality of rigid areas; and
a plurality of first line patterns disposed in the soft area, and the plurality of first line
patterns connects the plurality of first plate patterns to each other,
wherein the plurality of second heat dissipation layers overlaps an area between the
plurality of first line patterns.

7. The display device according to claim 6, further comprising:
a plurality of connection lines disposed on the plurality of first line patterns,
wherein the plurality of connection lines and the plurality of heat dissipation lines do not
overlap each other.

8. The display device according to claim 7, wherein the plurality of connection lines
and the plurality of heat dissipation lines are formed in a sinusoidal shape.

9. The display device according to claim 7, wherein the upper substrate contacts a
portion of the lower substrate exposed from the plurality
of first plate patterns and the plurality of first line patterns, and
the upper substrate is disposed to surround the plurality of light emitting elements on the
plurality of first plate patterns.

10. The display device according to claim 1, wherein the plurality of first heat
dissipation layers includes a base material and a first conductive material,
the plurality of second heat dissipation layers includes the base material and a second
conductive material,
the first conductive material comprises a nanowire, and
the second conductive material comprises a thermally conductive filler including a
conductive material.

11. The display device according to claim 1, wherein the plurality of first heat
dissipation layers is transparent, and the plurality of second heat dissipation layers is opaque.

12. The display device according to claim 1, wherein the upper substrate further
includes a plurality of additional holes overlapping the plurality of rigid areas, and
a portion of the plurality of first heat dissipation layers is exposed to an outside of the
display device by the plurality of additional holes.

13. The display device according to claim 12, wherein each of the plurality of
additional holes has a size smaller than a size of each of the plurality of first heat dissipation
layers.

14. A display device, comprising:
a lower substrate;
a plurality of first plate patterns disposed on the lower substrate and spaced apart from each other;
a plurality of first line patterns disposed between the plurality of first plate patterns;
a plurality of light emitting elements disposed on the plurality of first plate patterns;
a plurality of first heat dissipation layers disposed on the plurality of first plate patterns
and the plurality of light emitting elements, the plurality of first heat dissipation layers contacting
the plurality of light emitting elements;
a plurality of heat dissipation lines extending from the plurality of first heat dissipation
layers to an area between the plurality of first plate patterns and an area between the plurality of
first line patterns;
an upper substrate covering the plurality of first heat dissipation layers and the plurality
of heat dissipation lines, the upper substrate including a plurality of holes; and
a plurality of second heat dissipation layers disposed in the plurality of holes, the
plurality of second heat dissipation layers connected to the plurality of heat dissipation lines,
wherein a first connection line and a second connection line is disposed on the plurality
of first line patterns and extend in a first direction and a second direction, respectively, and the
plurality of heat dissipation lines extends in a direction different from the first direction and the
second direction.

15. The display device according to claim 14, wherein the upper substrate includes a
first portion connected to a surface of the lower substrate and curved along a surface of a
configuration of elements located between the upper substrate and the lower substrate, and
the plurality of heat dissipation lines includes a portion curved along a surface of the
upper substrate.

16. The display device according to claim 15, wherein the plurality of heat dissipation
lines is disposed on a side surface of the plurality of first plate patterns, and the plurality of heat
dissipation lines extends to the plurality of first heat dissipation layers on the plurality of first
plate patterns.

17. The display device according to claim 16, wherein the upper substrate further
includes a plurality of additional holes respectively corresponding to each of the plurality of first
heat dissipation layers, and each of the plurality of additional holes has a diameter smaller than a
minimum width of each of the plurality of first heat dissipation layers.

18. The display device according to claim 14, wherein the first connection line, the
second connection line, and the plurality of heat dissipation lines are each formed in a sinusoidal
shape.

19. The display device according to claim 14, wherein the plurality of first heat
dissipation layers is transparent, and the plurality of second heat dissipation layers is opaque.

20. A display device, comprising:
a lower substrate including a plurality of rigid areas and a soft area surrounding the plurality of rigid areas;
a plurality of light emitting elements respectively disposed in the plurality of rigid areas;
a heat dissipation unit thermally connected to the plurality of light emitting elements; and
an upper substrate disposed over the plurality of light emitting elements and the heat
dissipation unit,
wherein the heat dissipation unit comprises:
a plurality of first heat dissipation layers respectively disposed in the plurality of rigid
areas and on the plurality of light emitting elements;
a plurality of second heat dissipation layers disposed in the soft area; and
a plurality of heat dissipation lines extending between the plurality of first heat
dissipation layers and the plurality of second heat dissipation layers, the plurality of heat
dissipation lines thermally connecting the plurality of first heat dissipation layers and the
plurality of second heat dissipation layers,
wherein the plurality of first heat dissipation layers, the plurality of second heat
dissipation layers, and the plurality of heat dissipation lines together form a continuous thermal-
dissipation path configured to dissipate heat generated by the plurality of light emitting elements
to an exterior of the display device.

21. The display device of claim 20, wherein each of the plurality of heat dissipation
lines bridges a boundary between the plurality of rigid areas and the soft area.

22. The display device of claim 20, wherein the second heat dissipation layers
comprise a flexible thermally conductive polymer.

23. The display device of claim 20, wherein the plurality of heat dissipation lines
comprise a metal having high thermal conductivity and selected from the group including
copper, silver, molybdenum, and aluminum.
